(19) United States
(12) Patent Application Publication
(10) Pub. No.: US 2010/0164054 A1
(43) Pub. Date: Jul. 1, 2010

(54) SEMICONDUCTOR DEVICE AND METHOD FOR MANUFACTURING THE SAME

(76) Inventor: YONG GEUN LEE, Chungbuk (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/638,443

(22) Filed: Dec. 15, 2009

(30) Foreign Application Priority Data
Dec. 31, 2008 (KR) 10-2008-0137944

(51) Int. Cl. H01L 29/06; H01L 21/762

(52) U.S. Cl. 257/506; 438/435; 257/E29.02; 257/E21.546

(57) ABSTRACT

A semiconductor device and a method for manufacturing the same are provided. The semiconductor device can include a semiconductor substrate including a trench, a first oxide layer in the trench, a second oxide layer filled in the trench to form an insulating layer, and a silicon nitride layer interposed between the first and second oxide layers. The silicon nitride layer can be etched such that the silicon nitride layer is recessed from top surfaces of the semiconductor substrate and the second oxide layer, thereby forming a divot at a top corner of the trench.

### CROSS-REFERENCE TO RELATED APPLICATION

This application claims the benefit under 35 U.S.C. §119 of Korean Patent Application No. 10-2008-0137944, filed Dec. 31, 2008, which is hereby incorporated by reference in its entirety.

### BACKGROUND

The present invention relates to a semiconductor device and a method for manufacturing the same.

A shallow trench isolation (STI) layer is often used in high-integration semiconductor devices because an STI layer can be formed in a narrow area while still imparting superior insulating properties.

In order to form an STI layer, a trench for isolating devices (or regions within a device) is formed by etching a semiconductor substrate, and an insulating layer is filled in the trench. When the STI layer is formed, an edge of the insulting layer can sometimes fill in the trench such that it is positioned higher than the semiconductor substrate, thereby leading to the occurrence of a divot. Such a divot can cause an edge of a CVD oxide layer filled in the trench to be recessed.

### BRIEF SUMMARY

Embodiments of the subject invention provide a semiconductor device and a method for manufacturing the same, capable of improving characteristics of a transistor by controlling a depth of a divot.

Threshold voltage and on/off characteristics of a transistor may vary depending on a depth of a divot. Therefore, characteristics of a narrow width transistor can be adjusted by controlling the depth of the divot.

In one embodiment, a semiconductor device can include: a semiconductor substrate including a trench; a first oxide layer in the trench; a silicon nitride layer on the first oxide layer in the trench; and a second oxide layer on the silicon nitride layer and filled in the trench to form an insulating layer; wherein a height of an uppermost surface of the silicon nitride layer is lower than both a top surface of the semiconductor substrate and a top surface of the second oxide layer, thereby forming a divot at a top corner of the trench.

In another embodiment, a method for manufacturing a semiconductor device can include: forming a first silicon nitride layer on a semiconductor substrate; forming a trench in the semiconductor substrate by etching the first silicon nitride layer and the semiconductor substrate; forming a first oxide layer in the trench; forming a second silicon nitride layer on the first oxide layer such that the second silicon nitride layer is connected to the first silicon nitride layer; filling the trench with a second oxide layer; removing the first silicon nitride layer; and forming a divot by removing a portion of the second silicon nitride layer exposed at a top corner of the trench.

### BRIEF DESCRIPTION OF THE DRAWINGS

FIGS. 1 to 7 are cross-sectional views showing a method for manufacturing a semiconductor device according to an embodiment of the present invention.

### DETAILED DESCRIPTION

Hereinafter, a semiconductor device and a method for manufacturing the same will be described with reference to the accompanying drawings.

When the terms “on” or “over” are used herein, when referring to layers, regions, patterns, or structures, it is understood that the layer, region, pattern, or structure can be directly on another layer or structure, or intervening layers, regions, patterns, or structures may also be present. When the terms “under” or “below” are used herein, when referring to layers, regions, patterns, or structures, it is understood that the layer, region, pattern, or structure can be directly under the other layer or structure, or intervening layers, regions, patterns, or structures may also be present.

FIGS. 1 to 7 are cross-sectional views showing a method for manufacturing a semiconductor device according to an embodiment of the present invention.

Referring to FIG. 1, a first silicon nitride layer 150 can be formed on a semiconductor substrate 100. The first silicon nitride layer 150 can be formed through, for example, a low pressure chemical vapor deposition process. In certain embodiments, the first silicon nitride layer 150 can serve as a stopper in a chemical mechanical polishing (CMP) process to be performed later.

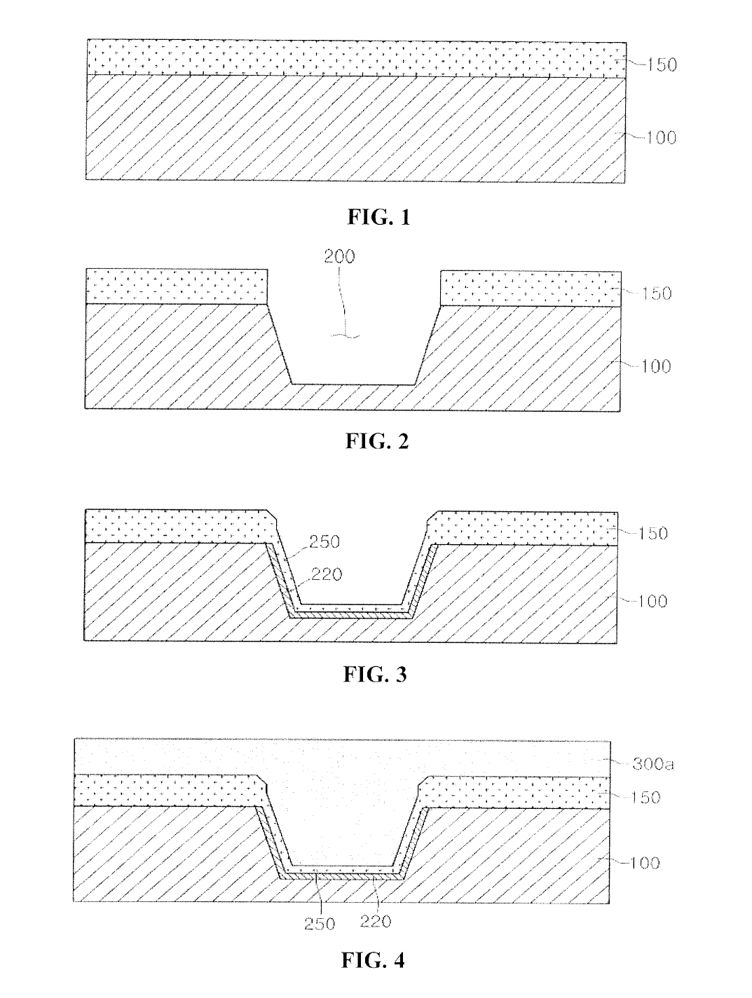

Then, referring to FIG. 2, a trench 200 can be formed in the semiconductor substrate 100 in a region where a shallow trench isolation (STI) will be formed later.

In order to form the trench 200, a trench area of the first silicon nitride layer 150 can be patterned through a photolithography process, thereby exposing a predetermined area of the semiconductor substrate 100 corresponding to the trench area. Then, the exposed semiconductor substrate 100 can be etched, thereby forming the trench 200. The semiconductor substrate 100 can be etched through, for example, a dry etching process. In an embodiment, the semiconductor substrate 100 can be etched by reactive ion etching (RIE).

Referring to FIG. 3, a first oxide layer 220 can be formed in the trench 200 (for example, on sidewalls and on a bottom surface of the trench 200), and a second silicon nitride layer 250 can be formed on the first oxide layer 220.

The first oxide layer 220 formed in the trench 200 can extend above the top surface of the semiconductor substrate 100 such that a height of the trench 200 is higher than a height of the top surface of the semiconductor substrate 100. In certain embodiments, the first oxide layer 220 can compensate for etch damage that may occur and/or can be used for rounding a top corner of the trench 200. The second silicon nitride layer 250 can be formed on the first oxide layer 220 such that the second silicon nitride layer 250 is connected to the first silicon nitride layer 150 formed at the top corner of the trench 200. Thus, the first silicon nitride layer 150 on the semiconductor substrate 100 can be physically connected to the second silicon nitride layer 250 formed in the trench, such that a silicon nitride layer can be formed over the whole surface of the semiconductor substrate 100, including within the trench 200.

Then, referring to FIG. 4, a second oxide layer 300a can be deposited on the semiconductor substrate 100. In an embodiment, the second oxide layer 300a can be deposited over the entire surface of the semiconductor substrate 100, including within the trench 200, such that the trench 200 can be filled with the second oxide layer 300a.

In an embodiment, the second oxide layer 300a can include a material having superior gap fill characteristics. For instance, the second oxide layer 300a can include tetraethyl orthosilicate (TEOS) material. The TEOS material can be deposited through, for example, a chemical deposition process.

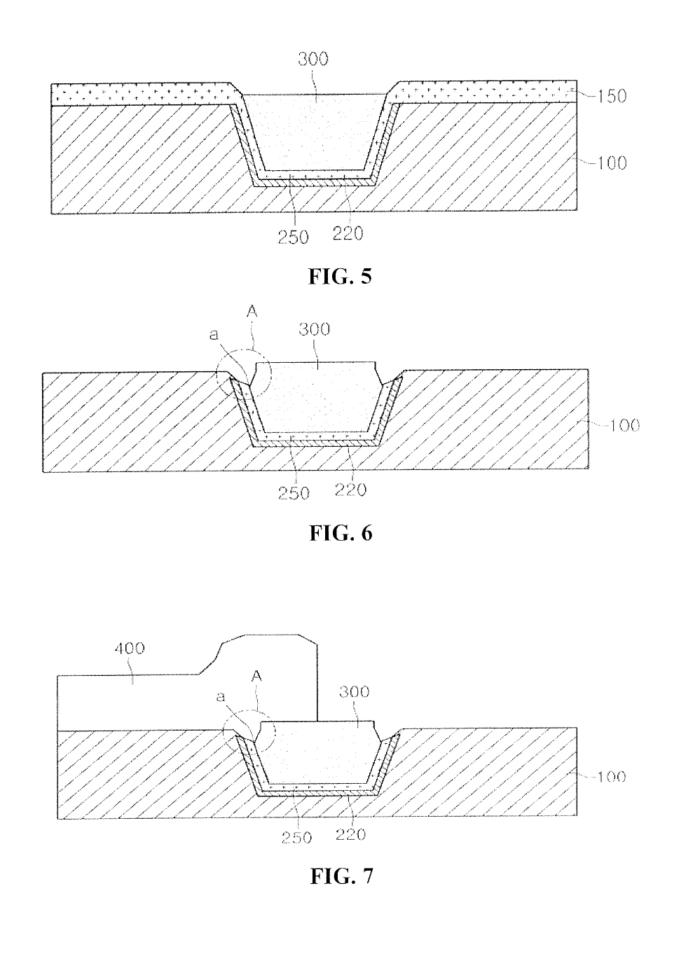

Next, referring to FIG. 5, the structure including the second oxide layer 300a can be planarized. In an embodiment, the structure including the second oxide layer 300a can be planarized through a CMP process.

In certain embodiments, when the CMP process is performed, the first silicon nitride layer 150 can serve as a stopper. Thus, at least a portion of the first silicon nitride layer 150 can remain on the semiconductor substrate 100, and the trench 200 can be filled with a second oxide layer 300 serving as an insulating layer.

Referring to FIG. 6, after the planarization process (e.g., after the CMP process), the remaining first silicon nitride layer 150 on the semiconductor substrate 100 can be removed.

The first silicon nitride layer 150 can be removed, for example, through a wet etching process using a predetermined etchant. In an embodiment, the first silicon nitride layer 150 is completely removed from the semiconductor substrate 100. In addition, a portion of the second silicon nitride layer 250 formed at the top corner A of the trench 200 can also be removed. In certain embodiments, a predetermined portion of the second silicon nitride layer 250 formed at the top corner A of the trench 200 can be removed.

The second silicon nitride layer 250 can be between the second oxide layer 300 and the first oxide layer 220 in the trench 200. The second silicon nitride layer 250 can be connected to the first silicon nitride layer 150 formed on the surface of the semiconductor substrate 100. Thus, if a portion of the second silicon nitride layer 250 is removed, a valley in the form of a divot a can be formed at the top corner A of the trench 200. A depth of the divot a can be easily adjusted by controlling the amount of the second silicon nitride layer 250 to be removed.

Referring to FIG. 7, in an embodiment, a third oxide layer 400 can be formed on the semiconductor substrate 100 and the second oxide layer 300 such that the divot a is completely buried in the third oxide layer 400 (i.e., the third oxide layer 400 completely covers the divot a). In certain embodiments, the third oxide layer 400 can serve as a gate oxide of a transistor.

As described above, according to embodiments of the present invention, an oxide layer and a silicon nitride layer can be sequentially formed in a trench (e.g. on a surface of the trench), and the trench can be filled with insulating material. Then, a predetermined portion of the silicon nitride layer formed at the top corner of the trench can be removed, thereby forming a divot. The depth of the divot can be easily adjusted by controlling selectivity between the oxide layer and the silicon nitride layer. Thus, the on/off characteristics of the transistor can be easily controlled by adjusting the depth of the divot. Additionally, the characteristics of the narrow width transistor can be easily adjusted, such that the performance of the narrow width transistor can be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a semiconductor substrate including a trench;
a first oxide layer in the trench;
a silicon nitride layer on the first oxide layer in the trench; and
a second oxide layer on the silicon nitride layer and filled in the trench to form an insulating layer;
wherein a height of an uppermost surface of the silicon nitride layer is lower than both a top surface of the semiconductor substrate and a top surface of the second oxide layer, thereby forming a divot at a top corner of the trench.

2. The semiconductor device according to claim 1, wherein a depth of the divot is adjustable according to a thickness of the silicon nitride layer.

3. The semiconductor device according to claim 1, wherein the second oxide layer comprises tetraethyl orthosilicate (TEOS) material.

4. The semiconductor device according to claim 1, wherein the silicon nitride layer has been etched such that the silicon nitride layer is recessed from the top surface of the semiconductor substrate and the top surface of the second oxide layer, thereby forming the divot at the top corner of the trench.

5. The semiconductor device according to claim 1, wherein the first oxide layer is on a surface of the trench.

6. The semiconductor device according to claim 1, wherein the first oxide layer is on a bottom surface of the trench and on sidewalls of the trench.

7. A method for manufacturing a semiconductor device, the method comprising:
forming a first silicon nitride layer on a semiconductor substrate;
forming a trench in the semiconductor substrate by etching the first silicon nitride layer and the semiconductor substrate;
forming a first oxide layer in the trench;
forming a second silicon nitride layer on the first oxide layer such that the second silicon nitride layer is connected to the first silicon nitride layer;
filling the trench with a second oxide layer;
removing the first silicon nitride layer; and
forming a divot by removing a portion of the second silicon nitride layer exposed at a top corner of the trench.

8. The method according to claim 7, wherein forming the second silicon nitride layer includes adjusting a thickness of the second silicon nitride layer according to a desired depth of the divot.

9. The method according to claim 7, wherein the forming of the second oxide layer includes:
depositing the second oxide layer on the semiconductor substrate such that a top surface of the second oxide layer is higher than a height of the trench; and
planarizing the second oxide layer using the first nitride layer as a stopper.

10. The method according to claim 7, wherein the second oxide layer includes TEOS material.

11. The method according to claim 7, wherein removing the first silicon nitride layer comprises performing a wet etching process.

12. The method according to claim 7, wherein forming the first oxide layer in the trench comprises forming the first oxide layer on a surface of the trench.

13. The method according to claim 7, wherein forming the first oxide layer in the trench comprises forming the first oxide layer on a bottom surface of the trench and on sidewalls of the trench.

14. The method according to claim 7, wherein forming the divot by removing a portion of the second silicon nitride layer exposed at the top corner of the trench comprises removing a portion of the second silicon nitride layer exposed at the top corner of the trench such that a height of an uppermost surface of the second silicon nitride layer is lower than both a top surface of the semiconductor substrate and a top surface of the second oxide layer.

15. The method according to claim 7, wherein a depth of the divot is adjustable according to a thickness of the second silicon nitride layer.

16. The method according to claim 7, wherein forming the divot by removing a portion of the second silicon nitride layer exposed at the top corner of the trench comprises removing a predetermined portion of the second silicon nitride layer exposed at the top corner of the trench.
